(19) United States
(12) Patent Application Publication
(10) Pub. No.: US 2024/0111923 A1
(43) Pub. Date: Apr. 4, 2024

(54) METHOD AND SYSTEM FOR OBTAINING ECOLOGICAL IMPACT MECHANISM

(71) Applicant: BEIHANG UNIVERSITY, Beijing (CN)

(72) Inventors: Weiying FENG, Beijing (CN); Jiayue GAO, Beijing (CN); Tengke WANG, Beijing (CN); Yuxin DENG, Beijing (CN); Fang YANG, Beijing (CN); Yingnan CAO, Beijing (CN); Yunping HAN, Beijing (CN)

(73) Assignee: BEIHANG UNIVERSITY, Beijing (CN)

(21) Appl. No.: 18/387,860

(22) Filed: Nov. 8, 2023

Related U.S. Application Data
(63) Continuation of application No. PCT/CN2023/105827, filed on Jul. 5, 2023.

(30) Foreign Application Priority Data
Sep. 27, 2022 (CN) 202211179115.2

(51) Int. Cl. G06F 30/20

(52) U.S. Cl. CPC G06F 30/20

(57) ABSTRACT

A method and a system for obtaining ecological impact mechanism are provided. The method includes the following steps: S1, collecting samples: collecting water and sediment samples of different seasons, different locations, and different depths; S2, screening indexes: selecting indexes of characterization DOM information, microbial community information and environmental factor information; S3, determining indexes: determining the selected DOM information, microbial community information and environmental factor information in S2 to obtain index determination data; S4, preprocessing data: preprocessing the DOM information and the microbial community information based on the index determination data obtained in S3; and S5, establishing model: establishing latent variables based on screened indexes, allocating the latent variables to the model based on a sediment system and an interaction system of water and sediment, and establishing the model by importing data, setting the latent variables, constructing a path and checking the model.

### CROSS REFERENCE TO THE RELATED APPLICATIONS

This application is a continuation application of International Application No. PCT/CN2023/105827, filed on Jul. 5, 2023, which is based upon and claims priority to Chinese Patent Application No. 202211179115.2, filed on Sep. 27, 2022, the entire contents of which are incorporated herein by reference.

### TECHNICAL FIELD

The present disclosure relates to the field of ecological protection technology, in particular to a method and a system for obtaining ecological impact mechanism.

### BACKGROUND

Lake is an important part of the earth's water environment ecosystem, which is closely related to human activities. With the intensification of climate warming, the survival of lake ecosystem in cold and arid regions is threatened. However, there are many elements in the lake ecosystem and the composition is complex. In addition to the water quality indexes concerned by environmental monitoring, dissolved organic matter (DOM) and microorganisms are important components that researchers have to consider. In recent years, a large number of accurate and fast characterization technologies have been born, which guide the research direction of lake ecological management.

Three-dimensional fluorescence spectrum is widely used in the characterization of DOM in natural waters, which has the characteristics of high sensitivity, less sample usage, high repeatability and no damage to the structure of samples. Combined with parallel factor analysis, five components can be resolved, namely, tryptophan-like substances, tyrosine-like substances, dissolved biological metabolites, fulvic-like substances and humic-like substances. DOMs in lake water and sediment can be traced by the auxiliary analysis of fluorescence index and biological index. Therefore, three-dimensional fluorescence spectrum is an important tool for understanding the DOM of lakes.

High-resolution Fourier transform ion cyclotron resonance mass spectrometry (FT-ICR-MS) has become a reliable tool for in-depth molecular characterization, which can more finely distinguish molecular compounds that can not be distinguished by fluorescence spectrum. It determines the accurate mass-to-charge ratio (m/Z) by assigning the molecular formula to thousands of peaks in the mass spectra of a dom complex mixture. The ultra-high resolution of FT-ICR-MS can detect thousands of ions with different m/Z values in one mass spectra. On the basis of the precise mass accuracy of FT-ICR-MS, by applying basic chemical rules (such as the rules for nitrogen and the rules for calculating double bond equivalents), the molecular formula of an unknown substance can be calculated for each mass number when the composition of the possible elements is known. In the molecular formula calculation, all possible elemental compositions are iteratively combined for calculation until all possible molecular formulas are obtained whose total mass matches the given mass within the error range. An appropriate planning method can be used to find the optimal disassembly sequence. The optimal disassembly order here refers to the order that meets the specific disassembly objectives (such as disassembly cost, time, benefit, etc.). This process can be accomplished by a variety of optimization methods, such as natural heuristics, rule-based methods, stochastic simulation techniques, and so on.

With the development of computer technology, intelligent algorithms have brought new possibilities for mechanism research in the field of environment. By utilizing the powerful computing power of computers, it is possible to more deeply fit and analyze how environmental factors affect important environmental variables. For example, structural equation modeling (SEM) is a method to establish, estimate and test causal models. The model contains not only observable explicit variables, but also latent variables that cannot be observed directly. SEM can replace the methods of multiple regression, path analysis, factor analysis and covariance analysis to analyze the effect of single index on the whole and the relationship between single indexes. At present, the application of structural equation modeling in ecology is mainly to explore the impact of water quality indexes on other dependent variables, and there is no complete system for the comprehensive evaluation of microorganisms and DOMs.

In this study, a new method and a system to obtain the ecological impact mechanism was developed by integrating a variety of spectra and mass spectrometry characterization technologies and traditional models, which provides an important scientific basis and practical value for further in-depth study of the coupling relationship between ecological factors such as dissolved organic matter, microorganisms and water quality indexes in eutrophic lakes.

### SUMMARY

The objective of the present disclosure is to provide a method and a system to obtain the ecological impact mechanism. Through the newly developed coupling model and research method of ecological factors, the ideal fitting of microbial community structure, DOM and various environmental factors was realized, the influence chain of coupling effect among DOM, microorganisms and environmental factors was combed, and the degree of coupling effect was quantified, so as to contribute to clarifying the characteristics of DOM and microorganisms in lakes, improving the mutual influence mechanism of the environmental factors, the DOM composition, and the microbial communities.

In order to achieve the above effects, the present disclosure adopts the following technical solutions.

The method for obtaining the ecological impact mechanism based on the coupling relationship model of lake ecological elements includes the following steps:
S1, collecting samples: collecting water and sediment samples of different seasons, different locations, and different depths;
S2, screening indexes: selecting indexes of characterization DOM information, microbial community information and environmental factor information;
S3, determining indexes: determining the selected DOM information, microbial community information and environmental factor information in S2 to obtain index determination data;
S4, preprocessing data: preprocessing the DOM information and the microbial community information based on the index determination data obtained in S3; and
S5, establishing model: establishing latent variables based on screened indexes, allocating the latent variables to the model based on a sediment system and an interaction system of water and sediment, and establishing the model by importing data, setting the latent variables, constructing a path and checking the model.

Preferably, S2, a result of indexes screened:
the characterization DOM information includes: a fluorescence index FI characterizing the source of DOM, a humification index HIX characterizing the humification degree of DOM, and a biological index BIX characterizing newly generated DOM;
the microbial community information includes: selecting species with high abundance and obvious seasonal variation at different taxonomic levels as the key species index of the model, and adding five alpha diversity indexes Ace, Chao, Sobs, Simpson, Shannon to character the microbial diversity; and
the environmental factor information includes: basic water quality indexes: water temperature, dissolved oxygen, and pH, nutritional indexes: total carbon in sediment, total nitrogen in sediment, total organic carbon in water and total nitrogen in water.

Preferably, S3, a specific content of determining indexes comprises: determining the DOM information through three-dimensional fluorescence and high-resolution Fourier transform ion cyclotron resonance mass spectrometry; determining the microbial community information through 16s RNA high-throughput sequencing technology; determining physical and chemical indexes of the environmental factor information.

Preferably, S4, a specific content of preprocessing data comprises: analysing a fluorescence spectrum by parallel factor analysis and after the components were analyzed, the relative fluorescence intensity is used to characterize the content of each fluorescent component; at the same time, calculating the biological index BIX, fluorescence index FI and humification index HIX, and the alpha diversity index of microbial community information, and selecting 3-5 key species based on the main environmental issues and relative abundance of species studied in the lake.

Preferably, S5, the model establishment specifically includes the following steps:
S501, importing the data: saving and sorting all index determination data in comma-separated values (CSV) format, with a row title as a sample name and a column title as an index name;
S502, setting the latent variables: setting three latent variables of water DOM, sediment DOM and DOM molecules as the DOM information, setting two latent variables of key species and microbial diversity as the microbial community information, and setting three latent variables of environmental variables, water nutrients and sediment nutrients as the environmental factor information; the key species, the water nutrients and the sediment nutrients are formative variables, while others are reactive variables;
S503, constructing the path: classifying the indexes based on the system, and establishing corresponding structural equation models respectively, establishing the model separately with the DOM information and the microbial information as dependent variables, and verifying an existence of a mediating effect by adding paths between the dependent variables; and
S504, checking the model: setting a quantity of subsamples as a first preset value and a threshold of significance level as a second preset value to verify whether a model adaptability index GOF value is greater than a third preset value, and verify whether there is a mediating effect between dependent variables.

Preferably, judgment conditions in S504 for verifying whether there is a mediating effect between dependent variables include:
if p1 and p2 are significant and p3 is not significant, there is a complete mediating effect;
if p1, p2 and p3 are all significant, there is a partial mediating effect; and
p 1, p2, p3 are all path coefficients.

The system for obtaining the ecological impact mechanism based on the coupling relationship model of lake ecological elements includes: a samples collecting module, an indexes screening module, an indexes determining module, a data preprocessing module and a model establishing module;
the samples collecting module, connected with an input end of the indexes determining module, is configured to collect water and sediment samples of different seasons, different locations, and different depths;
the indexes screening module, connected with an input end of the indexes determining module, is configured to select indexes of characterization DOM information, microbial community information and environmental factor information;
the indexes determining module, connected with an input end of the data preprocessing module, is configured to determine the selected DOM information, microbial community information and environmental factor information to obtain index determination data;
the data preprocessing module, connected with an input end of the model establishing module, is configured to preprocess the DOM information and the microbial community information; and
the model establishing module is configured to establish latent variables based on screened data indexes and allocate the latent variables to the model based on a sediment system and an interaction system of water and sediment, and comprises a data importing module, a latent variables setting module, a path constructing module and a model checking module.

Preferably, the model establishing module specifically includes: a data importing unit, a latent variables setting unit, a path constructing unit and a model check unit.
the data importing unit, connected with an input end of the latent variables setting unit, is configured to save and sort all data of indexes in CSV format, with a row title as a sample name and a column title as an index name;
the latent variables setting unit, connected with an input end of the path constructing unit, is configured to set three latent variables of water DOM, sediment DOM and DOM molecules as the DOM information, set two latent variables of key species and microbial diversity as the microbial community information, and set three latent variables of environmental variables, water nutrients and sediment nutrients as the environmental factor information; the key species, the water nutrients and the sediment nutrients are formative variables, while others are reactive variables;
the path constructing unit connected with an input end of the model check unit, is configured to classify the indexes based on the system, establish corresponding structural equation models respectively, establish the model separately with the DOM information and the microbial community information as dependent variables, verify an existence of a mediating effect by adding paths between the dependent variables; and
the model check unit is configured to set a quantity of subsamples as a first preset value and a threshold of significance level as a second preset value to verify whether a model adaptability index GOF value is greater than a third preset value, and verify whether there is a mediating effect between dependent variables.

According to the technical solutions, compared with the prior art, the method has the beneficial effects that through the model, the relation among the ecological system elements such as DOM, microbial information and environmental factors can be represented on the level of latent variables, and the influence mechanism among the ecological elements can be explored in detail. There is a coupling relationship between DOM and microorganisms. DOM can be used by microorganisms, while the organic matter produced by microbial metabolism will become a part of DOM. At present, the analysis of the interaction between DOM and microorganisms is not clear and definite. In this model, the degree of interaction between the two variables can be analyzed by comparing the path coefficients of the same path in different directions which leads to the party that has a greater impact. By analyzing the mediating effect, a clear causal chain between latent variables can be obtained, thereby improving the impact mechanism.

### BRIEF DESCRIPTION OF THE DRAWINGS

In order to describe the technical solutions in the embodiments of the present disclosure more clearly, the accompanying drawings required to describe the embodiments are briefly described below. Apparently, the accompanying drawings described below are only some embodiments of the present disclosure. Those of ordinary skill in the art may further obtain other accompanying drawings based on these accompanying drawings without creative efforts.

FIG. 1 is a flowchart of the method for obtaining the ecological impact mechanism based on the coupling relationship model of lake ecological elements provided by the present disclosure;

FIG. 2 is a flowchart of the method of model establishment provided by the present disclosure;

FIG. 3 is a schematic diagram of the mediation effect provided by the present disclosure;

FIG. 4 shows the impact model of DOM and environmental factors on microbial communities in the sediment system provided by the present disclosure;

FIG. 5 shows the impact model of microbial communities and environmental factors on DOM in the sediment system provided by the present disclosure;

FIG. 6 shows the impact model of DOM and environmental factors on microbial communities in the water and sediment interaction system provided by the present disclosure;

FIG. 7 shows the impact model of microbial communities and environmental factors on DOM in the water and sediment interaction system provided by the present disclosure;

FIG. 8 is a system diagram of the ecological impact mechanism obtained based on the coupling relationship model of lake ecological elements provided by the present disclosure;

FIG. 9 shows the system diagram of the model establishment module provided by the present disclosure; and

FIG. 10 schematic diagram of the model establishment provided by the present disclosure.

### DETAILED DESCRIPTION OF THE EMBODIMENTS

The present disclosure will now be further described with reference to the accompanying drawings and embodiments, it being apparent that the embodiments described are only a portion of the embodiments of the present disclosure, and not all of the embodiments. Based on the embodiments of the present disclosure, all other embodiments obtained by those skilled in the art without creative work are within the scope of the present disclosure.

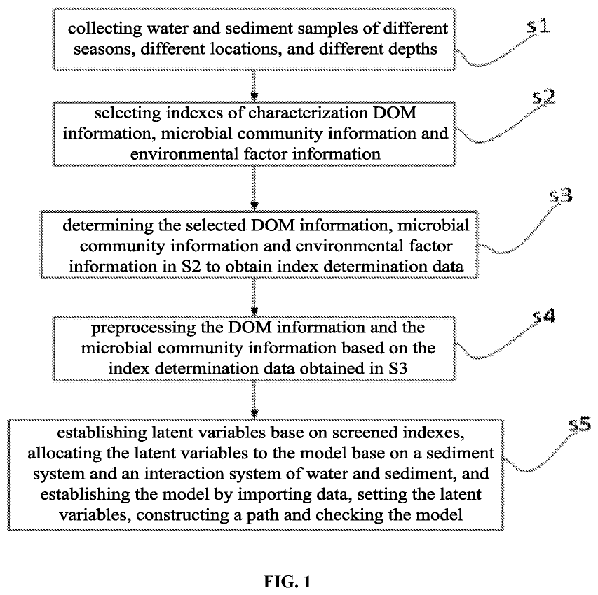

As shown in FIG. 1, a method for obtaining the ecological impact mechanism based on the coupling relationship model of lake ecological elements provided by the present disclosure comprises the following steps:
S1, collecting samples: collecting water and sediment samples of different seasons, different locations, and different depths;
S2, screening indexes: screening DOM, microbial community information and environmental factor information based on the collected samples;
S3, determining indexes: determining the selected DOM information, microbial community information and environmental factor information;
S4, preprocessing data: preprocessing the DOM information and the microbial community information based on the index determination; and
S5, establishing model: establishing latent variables based on screened data indexes, allocating the latent variables to the model based on a sediment system and an interaction system of water and sediment, and establishing the model by importing data, setting the latent variables, constructing a path and checking the model.

Furthermore, the sample size in S1 should not be less than 10 times of the number of model paths in the subsequent latent variables, and the sampling points should be dispersed as much as possible. If there are significant external inputs (such as rivers and sewage outlets), the sampling density should be increased appropriately.

Furthermore, S2, a result of indexes screened:
the characterization DOM information includes: a fluorescence index FI characterizing the source of DOM, a humification index HIX characterizing the humification degree of DOM, and a biological index BIX characterizing newly generated DOM;
the microbial community information includes: selecting species with high abundance and obvious seasonal variation at different taxonomic levels as the key species index of the model, and adding five alpha diversity indexes Ace, Chao, Sobs, Simpson, Shannon to character the microbial diversity; and
the environmental factor information includes: basic water quality indexes: water temperature, dissolved oxygen, and pH, nutritional indexes: total carbon in sediment, total nitrogen in sediment, total organic carbon in water and total nitrogen in water.

Specifically, the indexes in S2 are selected from three aspects: DOM, microorganisms and environmental factors. Three-dimensional fluorescence spectrum can provide the component information of water and sediment, and the abundance of all components analyzed by parallel factor analysis is selected as the model index, at the same time, in order to supplement the unrecognized fluorescence information, the fluorescence index FI representing the DOM source, the humification index HIX representing the degree of DOM humification, and the biological index BIX representing the newly generated DOM were selected as supplements to the DOM component information, striving to comprehensively and comprehensively summarize the DOM component information. High-resolution Fourier transform ion cyclotron resonance mass spectrometry (FT-ICR-MS) can provide the composition information of DOM from the molecular level. Considering that the information required by the model needs to be highly generalized, the relative molecular mass and aromaticity are selected as the model indexes. The microbial information is detected by 16s-RNA high-throughput sequencing technology, the species with high abundance and obvious seasonal changes at different classification levels are selected as the key species indexes of the model, and five commonly used alpha diversity indexes (Ace, Chao, Sobs, Simpson and Shannon) are added to represent the microbial diversity. The microbial information in the lake system is comprehensively summarized. The environmental factor index includes: basic water quality indexes: water temperature, dissolved oxygen, and pH, nutritional indexes: total carbon in sediment, total nitrogen in sediment, total organic carbon in water and total nitrogen in water.

Where, the specific meanings of the alpha diversity indexes Ace, Chao, Sobs, Simpson and Shannon are as follows.

Ace: an index used to estimate the number of OTUs in a community which is proposed by Chao. It is one of the commonly used indices in ecology to estimate the total number of species, and differs from the algorithm of Chao's index.

Chao: it adopts the Chao algorithm to calculate the number of OTUs detected only once and twice in a community, and estimate the actual number of species present in the community. The Chao index is commonly used in ecology to estimate the total number of species, and was first proposed by Chao (1984).

The greater the Chao value, the greater the total number of species.

Chao=Sobs+n1(n1−1)/2(n2+1).
where Chao is the estimated number of OTUs, Sobs is the observed number of OTUs, n1 is the number of OTU with only one sequence, and n2 is the number of OTU with only two sequences.

Simpson: one of the diversity indices used to estimate the microorganisms in a sample, proposed by Edward Hugh Simpson (1949), is often used in ecology to quantitatively describe the biodiversity of an area. The greater the Simpson index, the higher the diversity of the community.

Shannon: one of the diversity indices used to estimate microorganisms in a sample. It and Simpson's diversity index are commonly used to reflect the diversity of a. The greater the Shannon value, the higher the diversity of the community.

Furthermore, S3, a specific content of determining indexes includes: determining the DOM information through three-dimensional fluorescence and high-resolution Fourier transform ion cyclotron resonance mass spectrometry (FT-ICR-MS); determining the microbial community information through 16s RNA high-throughput sequencing technology; determining physical and chemical indexes of the environmental factor information.

Specifically, For DOM in S3, it shall be determined by three-dimensional fluorescence and FT-ICR-MS. Take 0.5 g of sediment powder after cold dry grinding and sieving, and extract it with ultrapure water at a ratio of 1:60 at 20 centigrade for 16 h. Take the supernatant and filter it through a 0.4511 m filter membrane to obtain the sediment extract. A molecular fluorescence spectrometer was configured to determine the fluorescence spectra of water samples, with a 150W xenon lamp as the excitation light source, a PMT voltage of 700V, an excitation wavelength of 200-600 nm, an emission wavelength of 250-600nm, a grating width of 5 nm, and ultrapure water as the blank correction. The DOM in the sediment extract was concentrated using a PPL (Bond Elut PPL) solid phase extraction cartridge. The cartridge was activated with 1 column volume of methanol and 3 column volumes of acidified water (hydrochloric acid, pH=2), and then 200mL of the sediment extract was added. The cartridge was eluted with 3 column volumes of acidified water to remove the salt, and the cartridge was dried with nitrogen. And finally, elute that DOM by using methanol of which the volume is one time of that of the column, where the liquid obtain by the elution is the concentrated solution to be detected. The determination was performed using a Bruker APEX Ultra FT-ICR mass spectrometer with a 9.4 T superconducting magnet and an Apollo II electrospray ion source (ESI) operated in negative ion mode, and the sample was injected into the ESI source by a syringe pump at a rate of 200 μL/H. A full scan was performed with 3.5 kV emitter voltage, 4.0 kV capillary column introduction voltage, and −320V capillary column end voltage in the charge-to-mass ratio range of 150-1000. The data were analyzed with Bruker Daltonics software after the test.

Microbial community information shall be determined by 16s-RNA high-throughput sequencing technology. Sediment samples stored at −80 centigrade shall be melted on ice, centrifuged and mixed, and then Nanodrop 2000 ultramicro spectrophotometer shall be configured to determine DNA purity and concentration in accordance with the determination requirements. At the same time, 1% agarose gel electrophoresis shall be adopted to determine DNA integrity. PCR amplification was performed after the detection, and the V3-V4 region was amplified using the universal primers 338F and 806R of bacterial 16s rRNA.

For the environmental factor information, it is mainly the determination of physical and chemical indexes. The basic water quality indexes such as pH, dissolved oxygen, water temperature and salinity are determined by portable water quality monitors. TOC is determined by Shimadzu TOC instrument. Sediment TC and TN are determined by elemental analyzer. Water TN is determined by spectrophotometer specified in the national standard.

Furthermore, S4, a specific content of preprocessing data comprises: analysing a fluorescence spectrum by parallel factor analysis and after the components were analyzed, the relative fluorescence intensity is used to characterize the content of each fluorescent component; at the same time, calculating the biological index BIX, fluorescence index FI and humification index HIX, and the alpha diversity index of microbial community information, and selecting 3-5 key species based on the main environmental issues and relative abundance of species studied in the lake.

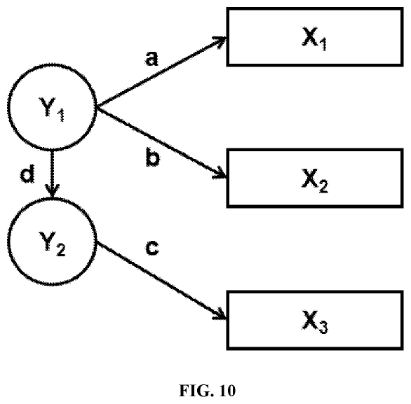

Furthermore, the main contents of S5 model establishment are as follows: importing the screened data indexes, i.e. Xn in FIG. 10, establishing the latent variables according to the ecological logic between the indexes, i.e. Yn in FIG. 10, and allocating them to the model according to the system (sediment system, interactive system of water and sediment). According to the main research object, the path pointing to the specific latent variable is established. After the model construction is completed, it is equivalent to the construction of equations:

$$\{ \begin{matrix}{Y}_{1} = a {X}_{1} + b {X}_{2} + {ε}_{1} \\ {Y}_{2} = c {X}_{3} + {ε}_{2} \\ {Y}_{2} = {dY}_{1} + {ε}_{3}\end{matrix}$$

After iterative calculation, the three load coefficients a, b and c (the contribution of the index to the latent variable) and the path coefficient d (the influence between the latent variables) are obtained. The analysis of the model mainly focuses on the path coefficient.

Furthermore, the model establishment in S5 includes: S501 importing the data, S502 setting the latent variables, S503 constructing the path and S504 checking the model.

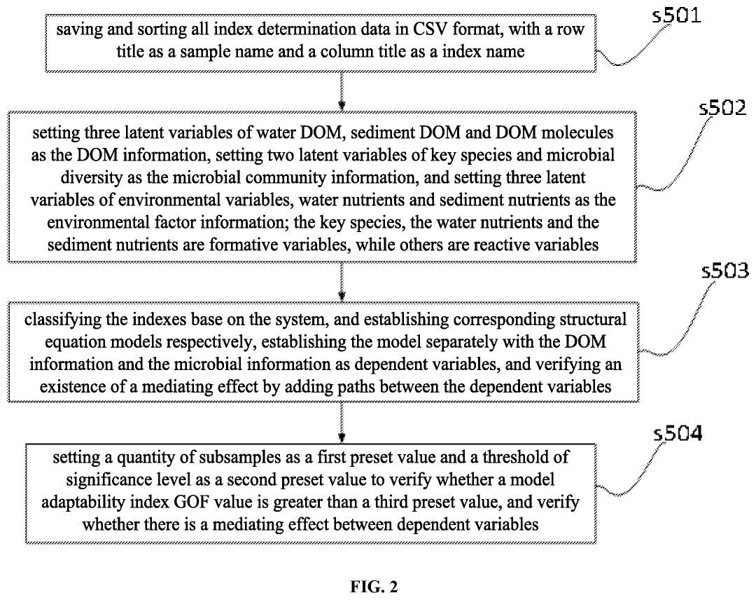

As shown in FIG. 2, the specific steps for constructing S5 are as follows:
S501, importing the data: saving and sorting all index determination data in CSV format, with a row title as a sample name and a column title as an index name to minimize the presence of missing values.
S502, setting the latent variables: the setting rules of latent variables should be based on ecological basis, and the indexes with certain similarities or interactions should be summarized as a comprehensive variable which can not be directly measured and plays a key role. In this model, setting three latent variables of water DOM, sediment DOM and DOM molecules as the DOM information, setting two latent variables of key species and microbial diversity as the microbial community information, and setting three latent variables of environmental variables, water nutrients and sediment nutrients as the environmental factor information finally; the key species, the water nutrients and the sediment nutrients are formative variables, while others are reactive variables. In addition, if the lake being studied has special environmental issues, latent variables can be set separately. For example, in recent years, there is an environmental problem of intensified salinization in Daihai Lake, so salinity can be set separately as a special variable in the environmental factor to be added to the model to explore the impact of salinity on DOM and microorganisms.
S503, constructing the path: different from the prior structural equation model in which all indexes are directly and completely blended, the present disclosure requires that the indexes are classified according to a system, such as a sediment system, an interactive system of a water body and a microorganism, and the like, corresponding structural equation models are respectively established, and for each model, DOM and microorganism information are respectively discussed through the direction of a path, that is establishing the model separately with the DOM information and the microbial information as dependent variables, and verifying an existence of a mediating effect by adding paths between the dependent variables.
S504, checking the model: the maximum number of iterations of the model is 300, converging to 10⁻⁷. In order to verify the significance of the path coefficient, the self-service method is used to calculate the p-value, and the number of sub samples is set to 500, with a significance level threshold of 0.05.

Furthermore, it is necessary to verify whether the Goodness of fitting (GOF) value of the model adaptability index is greater than 0.36 to ensure the overall rationality and effectiveness of the model. When analyzing, the significant portion of the path coefficient can be selected for causal analysis, and the explanation of mediating effects should be focused on.

Furthermore, judgment conditions in S504 for verifying whether there is a mediating effect between dependent variables include:
if p1 and p2 are significant and p3 is not significant, there is a complete mediating effect;
if p1, p2 and p3 are all significant, there is a partial mediating effect; and
p 1, p2, p3 are all path coefficients.

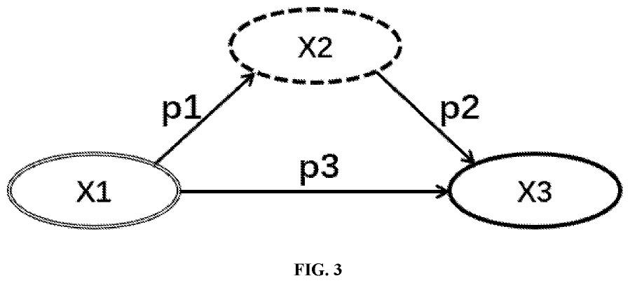

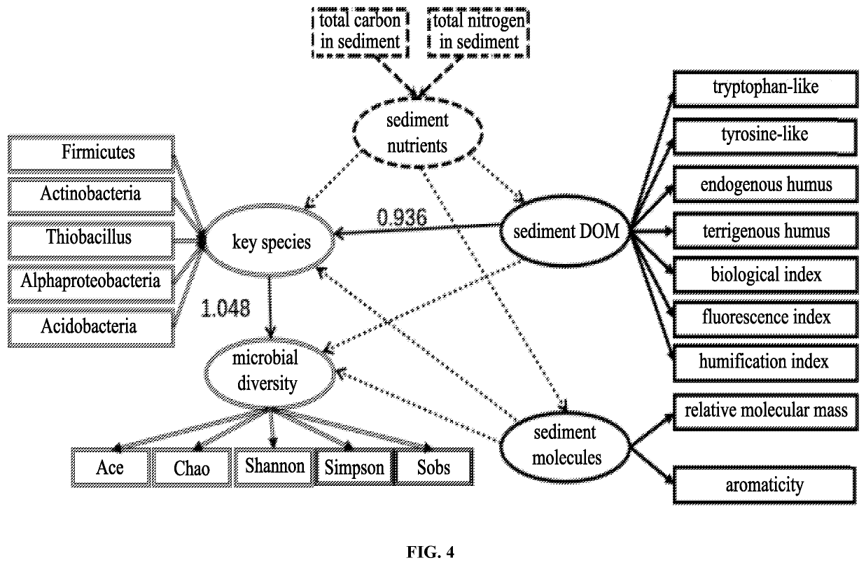

Specifically, p1, p2, and p3 are path coefficients, where the variable at the beginning of the arrow changes by 1 and the variable at the end changes by pn, which are used to explain the mediating effect and are not presented in the model as specific variables. As shown in FIG. 4, sediment DOM, key species, and microbial diversity constitute a mediating effect as shown in FIG. 3, with p1 being 0.936 and p2 being 1.048. Therefore, p3 is not significant and is not given, indicating a complete mediating effect.

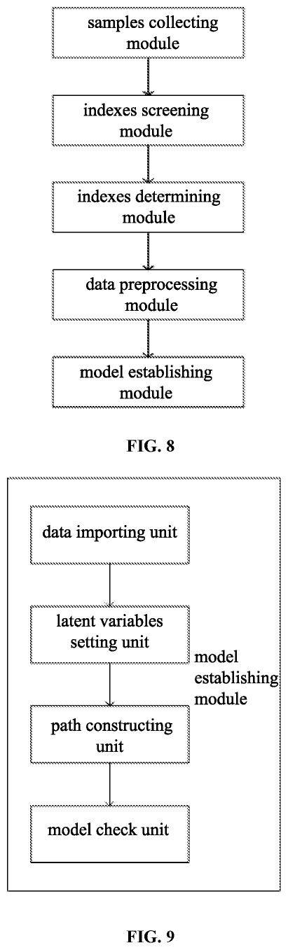

Furthermore, the embodiment of the present disclosure also provides a system for obtaining the ecological impact mechanism based on the coupling relationship model of lake ecological elements, corresponding to the method described in FIG. 1, for the specific implementation of the method in FIG. 1. The system diagram is shown in FIG. 8, which specifically includes: a samples collecting module, an indexes screening module, an indexes determining module, a data preprocessing module and a model establishing module.

The samples collecting module, connected with an input end of the indexes determining module, is configured to collect water and sediment samples of different seasons, different locations, and different depths.

The indexes screening module, connected with an input end of the indexes determining module, is configured to select indexes of characterization DOM information, microbial community information and environmental factor information. The indexes determining module, connected with an input end of the data preprocessing module, is configured to determine the selected DOM information, microbial community information and environmental factor information to obtain index determination data.

The data preprocessing module, connected with an input end of the model establishing module, is configured to preprocess the DOM information and the microbial community information; and

The model establishing module is configured to establish latent variables based on screened data indexes and allocate the latent variables to the model based on a sediment system and an interaction system of water and sediment, and comprises a data importing module, a latent variables setting module, a path constructing module and a model checking module.

Furthermore, the model establishing module as shown in FIG. 9 includes: a data importing unit, a latent variables setting unit, a path constructing unit and a model check unit.

The data importing unit, connected with an input end of the latent variables setting unit, is configured to save and sort all data of indexes in CSV format, with a row title as a sample name and a column title as an index name.

The latent variables setting unit, connected with an input end of the path constructing unit, is configured to set three latent variables of water DOM, sediment DOM and DOM molecules as the DOM information, set two latent variables of key species and microbial diversity as the microbial community information, and set three latent variables of environmental variables, water nutrients and sediment nutrients as the environmental factor information; the key species, the water nutrients and the sediment nutrients are formative variables, while others are reactive variables.

The path constructing unit connected with an input end of the model check unit, is configured to classify the indexes based on the system, establish corresponding structural equation models respectively, establish the model separately with the DOM information and the microbial community information as dependent variables, verify an existence of a mediating effect by adding paths between the dependent variables. and

The model check unit is configured to set a quantity of subsamples as a first preset value and a threshold of significance level as a second preset value to verify whether a model adaptability index GOF value is greater than a third preset value, and verify whether there is a mediating effect between dependent variables.

As shown in FIG. 3, the figure selects five latent variables related to the sediment system, namely, sediment nutrients, sediment DOM, DOM molecules, key species and microbial diversity, and takes microbial information as the dependent variable to establish the path. The GOF of the model is 0.996, and after verifying the mediating effect. it was found that key species was a complete mediating variable between DOM and microbial diversity, which meant that DOM affected microbial diversity by affecting key species, and the path coefficients were 0.936 and 1.048, which were significant.

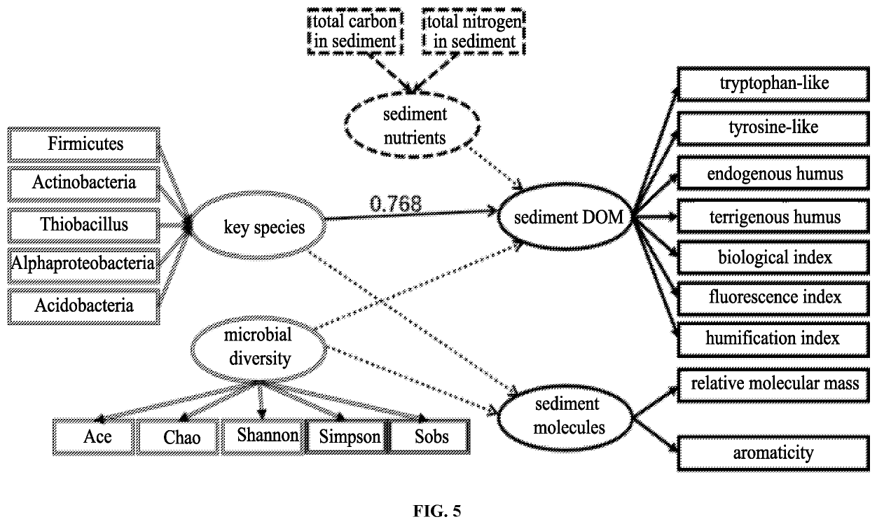

As shown in FIG. 5, they are all latent variables related to the sediment system, but the path is established by taking DOM as the dependent variable in FIG. 5, and the GOF of the model is 0.464. After verification, there is no mediating effect between the paths, and the key species have a significant impact on DOM, with a path coefficient of 0.768. Compared to FIG. 4, the difference of path coefficients in different directions of the same path indicates the influence of two indicators with coupling effect on each other. The comparison between FIG. 5 and FIG. 4, for example, indicates that in this example lake, the impact of DOM on microbial communities is greater than the reaction of microbial communities on DOM.

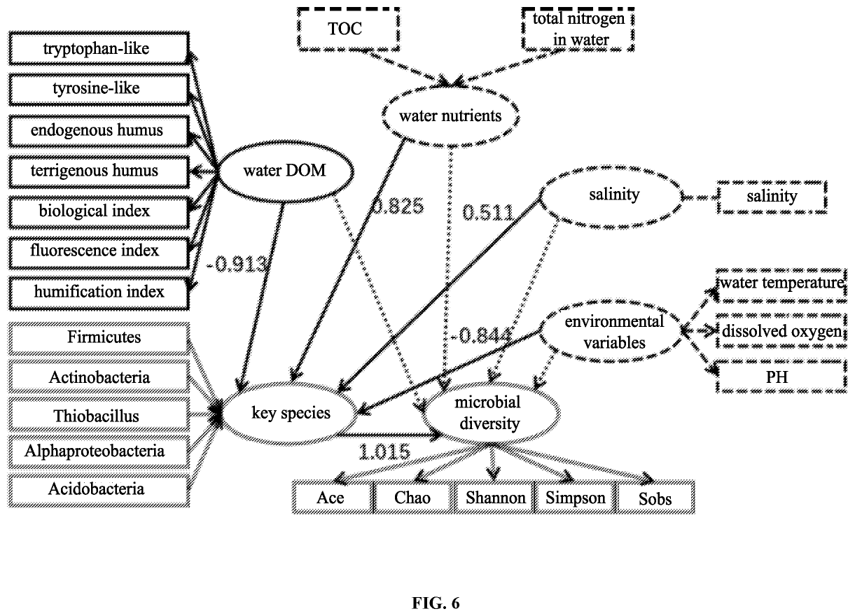

FIG. 6 selects six latent variables that interact in the water and sediment system, namely, water nutrients, water DOM, environmental variables, salinity, key species and microbial diversity. The GOF of the model is 0.995. After verifying the mediation effect, it is found that in this example, water DOM, nutrients, salinity and environmental variables all affected microbial diversity through the mediating effect of key species, and the path coefficients were −0.913, 0.825, 0.511 and −0.844 respectively. Negative path coefficients represent reverse effects, while positive path coefficients represent positive effects.

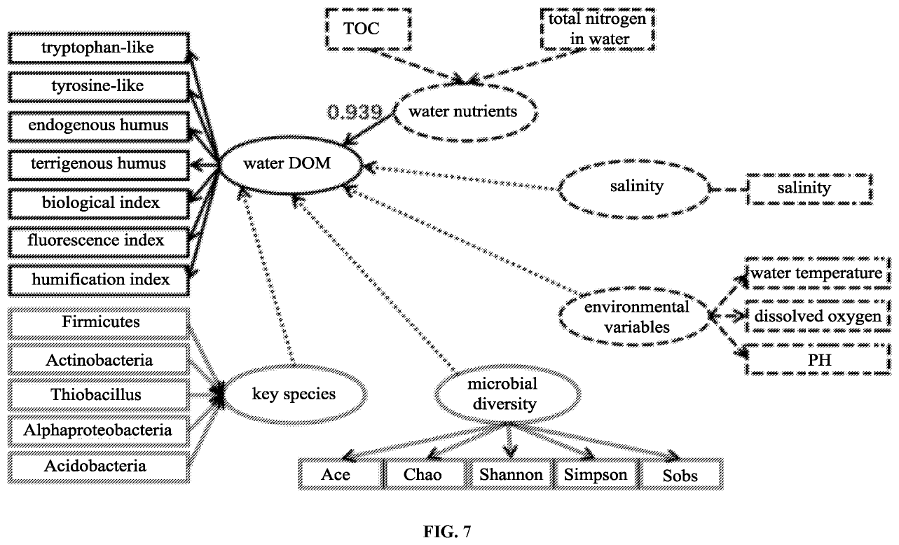

The present disclosure divides the structural equation model of the entire lake ecosystem into four modules (FIGS. 4-7). FIG. 4 and FIG. 5 show the sediment system, and the selected variables are sediment related variables. FIG. 6 and FIG. 7 show the interaction system between water and sediment, and the selected variables are water related variables and sediment microbial variables. FIG. 4 and FIG. 6 focus on microbial information as the main research variable, while FIG. 5 and FIG. 7 focus on DOM information as the main research variable.

Where, the numbers on the path in FIGS. 4-7 represent the path coefficient, the dashed line represents that the path coefficient is not significant, the solid line represents that the path coefficient is significant, and the arrow represents that the path direction.

In a specific embodiment, four fluorescent substances, namely tryptophan-like, tyrosine-like, endogenous humus and terrigenous humus, are resolved from the water body and sediments of the Daihai Lake through three-dimensional fluorescence spectrum analysis, and the key species of microorganisms are Firmicutes, Actinobacteria, Alphaproteobacteria, Acidobacteria and Thiobacillus. After analyzing the sediment system and the interaction system of water and sediment with DOM and microbial information as dependent variables respectively, the conclusions are as follows:

The DOM in sediment significantly affects microbial communities and has a mediating effect. DOM improves microbial diversity by promoting key species.

Relatively, key species significantly promote the generation of DOM in sediments, but the impact is not as significant as the impact of DOM on key species.

Environmental factors significantly affect microbial communities and have mediating effects. The effects of salinity, water quality, and nutrients in water on microbial diversity are achieved by affecting key species. Additionally, DOM in water bodies affects microbial diversity by inhibiting key species.

There is a significant positive correlation between nutrients in water and the abundance of DOM in water, mainly because TOC represents the total amount of DOM. Other latent variables do not have a significant impact on DOM.

This model clearly sorts out the complex ecological elements of Daihai according to the system, clarifies the logical chain of the impact of environmental disturbances on the ecosystem, and contributes to the protection of lake ecosystems in cold and arid regions.

It will be apparent to a person of ordinary skill in the art that the present disclosure is not limited to the details of the above-described exemplary embodiments, and that the present disclosure can be embodied in other specific forms without departing from the spirit or essential characteristics thereof. The present embodiments are therefore to be considered in all respects as illustrative and not restrictive, the scope of the disclosure being defined by the appended claims rather than by the foregoing description, and all changes which come within the meaning and range of equivalency of the claims are therefore intended to be embraced therein. Any reference signs in the claims shall not be construed as limiting the claim to which they relate.

Further, a person of ordinary skill is enabled to make or use the present disclosure. Many modifications to these embodiments will be readily apparent to those of ordinary skill in the art, and the generic principles defined herein may be implemented in other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. A method for obtaining an ecological impact mechanism based on a coupling relationship model of lake ecological elements, comprising:
S1, collecting samples: collecting water and sediment samples of different seasons, different locations, and different depths;
S2, screening indexes: selecting indexes of characterization dissolved organic matter (DOM) information, microbial community information and environmental factor information;
S3, determining indexes: determining the selected DOM information, microbial community information and environmental factor information in S2 to obtain index determination data;
S4, preprocessing data: preprocessing the DOM information and the microbial community information based on the index determination data obtained in S3; and
S5, establishing a model: establishing latent variables based on screened indexes, allocating the latent variables to the model based on a sediment system and an interaction system of water and sediment, and establishing the model by importing data, setting the latent variables, constructing a path and checking the model;
S5, the step of establishing the model comprises the following steps:
S501, importing the data: saving and sorting all index determination data in a comma-separated values (CSV) format, with a row title as a sample name and a column title as an index name;
S502, setting the latent variables: setting three latent variables of water DOM, sediment DOM and DOM molecules as the DOM information, setting two latent variables of key species and a microbial diversity as the microbial community information, and setting three latent variables of environmental variables, water nutrients and sediment nutrients as the environmental factor information; the key species, the water nutrients and the sediment nutrients are formative variables, while the water DOM, the sediment DOM, the DOM molecules, the microbial diversity, and the environmental variables are reactive variables;
S503, constructing the path: classifying the indexes based on the system, and establishing corresponding structural equation models respectively, establishing the model separately with the DOM information and the microbial community information as dependent variables, and verifying an existence of a mediating effect by adding paths between the dependent variables; and
S504, checking the model: setting a quantity of subsamples as a first preset value and a threshold of significance level as a second preset value to verify whether a model adaptability index goodness of fitting (GOF) value is greater than a third preset value, and verify whether there is a mediating effect between the dependent variables.

2. The method for obtaining the ecological impact mechanism based on the coupling relationship model of the lake ecological elements according to claim 1, wherein
S2, a result of indexes screened:
the characterization DOM information comprises: a fluorescence index (FI) characterizing a source of DOM, a humification index (HIX) characterizing a humification degree of DOM, and a biological index (BIX) characterizing newly generated DOM;
the microbial community information comprises: selecting species with high abundance and obvious seasonal variation at different taxonomic levels as the key species index of the model, and adding five alpha diversity indexes to character the microbial diversity; and
the environmental factor information comprises: basic water quality indexes: a water temperature, a dissolved oxygen, and a pH; nutritional indexes: a total carbon in sediment, a total nitrogen in sediment, a total organic carbon in water and a total nitrogen in water.

3. The method for obtaining the ecological impact mechanism based on the coupling relationship model of the lake ecological elements according to claim 1, wherein
S3, a content of determining indexes comprises: determining the DOM information through a three-dimensional fluorescence and a high-resolution Fourier transform ion cyclotron resonance mass spectrometry; determining the microbial community information through a 16s RNA high-throughput sequencing technology; determining physical and chemical indexes of the environmental factor information.

4. The method for obtaining the ecological impact mechanism based on the coupling relationship model of the lake ecological elements according to claim 1, wherein
S4, a specific content of preprocessing data comprises: analysing a fluorescence spectrum by a parallel factor analysis and after the components were analyzed, a relative fluorescence intensity is configured to characterize the content of each fluorescent component; at the same time, calculating the BIX, FI and HIX, and an alpha diversity index of the microbial community information.

5. The method for obtaining the ecological impact mechanism based on the coupling relationship model of the lake ecological elements according to claim 4, wherein
in S504, judgment conditions for verifying whether there is a mediating effect between the dependent variables are as follows:
if p1 and p2 are significant and p3 is not significant, there is a complete mediating effect;
if p1, p2 and p3 are all significant, there is a partial mediating effect; and
p1, p2, p3 are all path coefficients.

6. A system for obtaining an ecological impact mechanism based on a coupling relationship model of lake ecological elements, wherein the system is configured for the method according to claim 1, and comprises a samples collecting module, an indexes screening module, an indexes determining module, a data preprocessing module and a model establishing module, wherein
the samples collecting module, connected with an input end of the indexes determining module, is configured to collect water and sediment samples of different seasons, different locations, and different depths;
the indexes screening module, connected with an input end of the indexes determining module, is configured to select indexes of characterization DOM information, microbial community information and environmental factor information;
the indexes determining module, connected with an input end of the data preprocessing module, is configured to determine the selected DOM information, microbial community information and environmental factor information to obtain index determination data;
the data preprocessing module, connected with an input end of the model establishing module, is configured to preprocess the DOM information and the microbial community information; and
the model establishing module is configured to establish latent variables based on screened data indexes and allocate the latent variables to the model based on a sediment system and an interaction system of water and sediment, and comprises a data importing module, a latent variables setting module, a path constructing module and a model checking module;
the model establishing module comprises: a data importing unit, a latent variables setting unit, a path constructing unit and a model check unit;
the data importing unit, connected with an input end of the latent variables setting unit, is configured to save and sort all data of indexes in a CSV format, with a row title as a sample name and a column title as an index name;
the latent variables setting unit, connected with an input end of the path constructing unit, is configured to set three latent variables of water DOM, sediment DOM and DOM molecules as the DOM information, set two latent variables of key species and a microbial diversity as the microbial community information, and set three latent variables of environmental variables, water nutrients and sediment nutrients as the environmental factor information; the key species, the water nutrients and the sediment nutrients are formative variables, while the water DOM, the sediment DOM, the DOM molecules, the microbial diversity, and the environmental variables are reactive variables;
the path constructing unit connected with an input end of the model check unit, is configured to classify the indexes based on the system, establish corresponding structural equation models respectively, establish the model separately with the DOM information and the microbial community information as dependent variables, verify an existence of a mediating effect by adding paths between the dependent variables;
the model check unit is configured to set a quantity of subsamples as a first preset value and a threshold of significance level as a second preset value to verify whether a model adaptability index GOF value is greater than a third preset value, and verify whether there is a mediating effect between dependent variables.

7. The system according to claim 6, wherein in the method, S2, a result of indexes screened:
the characterization DOM information comprises: a fluorescence index (FI) characterizing a source of DOM, a humification index (HIX) characterizing a humification degree of DOM, and a biological index (BIX) characterizing newly generated DOM;
the microbial community information comprises: selecting species with high abundance and obvious seasonal variation at different taxonomic levels as the key species index of the model, and adding five alpha diversity indexes to character the microbial diversity; and
the environmental factor information comprises: basic water quality indexes: a water temperature, a dissolved oxygen, and a pH; nutritional indexes: a total carbon in sediment, a total nitrogen in sediment, a total organic carbon in water and a total nitrogen in water.

8. The system according to claim 6, wherein in the method, S3, a content of determining indexes comprises: determining the DOM information through a three-dimensional fluorescence and a high-resolution Fourier transform ion cyclotron resonance mass spectrometry; determining the microbial community information through a 16s RNA high-throughput sequencing technology; determining physical and chemical indexes of the environmental factor information.

9. The system according to claim 6, wherein in the method, S4, a specific content of preprocessing data comprises: analysing a fluorescence spectrum by a parallel factor analysis and after the components were analyzed, a relative fluorescence intensity is configured to characterize the content of each fluorescent component; at the same time, calculating the BIX, FI and HIX, and an alpha diversity index of the microbial community information.

10. The system according to claim 9, wherein in the method, in S504, judgment conditions for verifying whether there is a mediating effect between the dependent variables are as follows:
if p1 and p2 are significant and p3 is not significant, there is a complete mediating effect;
if p1, p2 and p3 are all significant, there is a partial mediating effect; and
p1, p2, p3 are all path coefficients.
